(19) United States
(12) Patent Application Publication
(10) Pub. No.: US 2007/0292769 A1
(43) Pub. Date: Dec. 20, 2007

(54) Method of Manufacturing Photomask Blank

(76) Inventor: Hideo Kobayashi, Kofu-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 10/590,663

(22) PCT Filed: Mar. 5, 2004
(86) PCT No.: PCT/JP04/02814

§ 371 Date: Jun. 1, 2007

(30) Foreign Application Priority Data
Aug. 12, 2002 (JP) 2002-234282

(51) Int. Cl. B05C 11/10; G03F 1/08; H01L 21/027

(52) U.S. Cl. 430/5; 156/345.19

(57) ABSTRACT

An unnecessary film removal device, an unnecessary film removal method, and a method of manufacturing a photomask blank, the unnecessary film removal device wherein a shield member (cover member) is installed apart a specified distance from the surface of a substrate so that chemicals are not fed to the portions where film is required, and a chemical guide member is installed on the outside of the shield member (cover member) so that the chemicals are fed to the peripheral edge parts of the substrate. On the shield member (cover member), a distance adjusting member for adjusting the distance thereof from the principal surface of the substrate is installed at three or more positions. The installation positions of the distance adjusting members are so arranged not to be disposed in a straight line when the installation positions are connected to each other with a straight line, and when the shield member (cover member) is rotated by a specified angle relative to the substrate about the surface center of the substrate, not to be overlapped with the installation positions of the distance adjusting members before the rotation, or a moving mechanism is installed in the distance adjusting members.

### TECHNICAL FIELD

This invention relates to an unnecessary-film removal apparatus and unnecessary-film removal method for removing an unnecessary film formed at part of the surface of a substrate, such as a photomask blank, a semiconductor substrate, a magnetic disk substrate, or a color filter, and a photomask blank manufacturing method using them.

### BACKGROUND ART

In the fields of manufacturing semiconductor substrates, photomasks and photomask blanks, magnetic disk substrates, color filters, and so on, it is often required to remove unnecessary portions of coating films and other films each formed on the main surface of the substrate.

When a resist, a resist bottom anti-reflective coating (BARC), a resist top anti-reflective layer (TARL), a resist top protective film, a conductive film, and so on (generically (collectively) referred to as a resist in this specification) are coated on a substrate by a spin coating method or the like, or coated in stack on the substrate, coating solutions are undesirably gathered at the peripheral portion of the surface of the substrate or extended to side surfaces of the substrate and are even extended along the back surface of the substrate, depending on conditions. In that case, a relatively thick film of the resist is irregularly formed at the peripheral portion of a photomask blank.

This resist formed at the peripheral portion of the substrate easily flakes, for example, due to contact with a container when the photomask blank is taken into and out of the container. Further, this thick film portion also easily flakes due to generation of cracks when subjected to a treatment with a chemical solution, such as a developer in a later mask manufacturing process, and thick film flakes become dust and adhere again to the photomask blank itself or various processing apparatuses, thereby finally causing defects of or causing a reduction in production yield of masks (including reticles) that are products using the photomask blank as an original material.

There is a case where an exposure apparatus has a structure of supporting the peripheral portion of a substrate when a photomask blank with a resist film formed on the main surface of the substrate is mounted on the apparatus. In this case, the photomask blank is not supported well if the peripheral portion of the substrate is partially protruded. Further, when the above-mentioned exposure apparatus is an electron-beam mask writing apparatus, there arises a problem that when grounding the photomask blank at the time of exposure, a ground probe does not contact well with an opaque film (a light-shielding film) that contains chromium as a main component and that is located under the resist film.

Therefore, in such a case, it is necessary to remove the unnecessary coating film at the peripheral portion of the substrate.

In order to solve the foregoing problems, Japanese Unexamined Patent Application Publication (JP-A) No. 2001-259502 discloses a method (FIG. 9) as a technique of removing the unnecessary resist film formed at the peripheral portion of the substrate. In this method of removing the unnecessary film, a cover member 3 having a number of fine holes formed at the peripheral portion of a substrate is placed over the substrate after coating of a resist film and, by supplying a chemical solution from above the cover member, the chemical solution is supplied to the peripheral portion of the substrate through the fine holes, thereby dissolving and removing the resist film formed at the peripheral portion of the substrate. Further, in order to ensure a constant distance between the substrate and the cover member so that the surface tension of the chemical substance acts to prevent soaking of the chemical solution to the center side of the substrate, threads (distance adjusting members) are passed through the foregoing holes at the same positions on respective sides and the substrate is held by a holding stage at two positions at each of four corners of the substrate.

However, in terms of increasing an effective area of the substrate (i.e. reducing an unnecessary-film removal area (width) near a chamfered face on the main surface of the substrate), precise control of a removal width, secure removal with no removal residue, and so on, the following problems have become outstanding with the conventional technique disclosed in Japanese Unexamined Patent Application Publication (JP-A) No. 2001-259502.

1) It has been considered that the diameter of each fine hole provided at the peripheral portion of the cover member is preferably as small as possible because if it is too large, a boundary between the removal area and the non-removal area becomes jagged and it becomes difficult to maintain mechanical strength of the cover member. However, when the hole diameter is small, since the chemical solution is supplied along an upper surface of the cover member, the supply amount of the chemical solution cannot be controlled with respect to the holes, so that the chemical solution is not sufficiently supplied to the removal area, and therefore, there has been a case where residue of the resist occurs at the peripheral portion of the substrate.

2) Since the threads (distance adjusting members) provided at the cover member for keeping constant the distance between the substrate and the cover member are in contact with the substrate even during the removal of the unnecessary film, the resist residue at contacting portions cannot be removed.

3) Since substrate holding members provided for holding the substrate are in contact with the substrate even during the removal of the unnecessary film, the resist residue at portions contacting the substrate holding members cannot be removed.

### DISCLOSURE OF THE INVENTION

It is an object of this invention to provide an unnecessary-film removal apparatus and unnecessary-film removal method that can solve the foregoing problems of the conventional technique and securely remove an unnecessary film (e.g. a resist) at the peripheral portion of a substrate and further provide a photomask blank manufacturing method which can prevent that a resist film at the peripheral portion of a substrate flakes and adheres again to a photomask blank itself or various processing apparatuses, thereby finally causing defects of or a reduction in production yield of photomasks that are produced by the use of the photomask blank as a feed material.

The photomask blank in this invention represents a photomask blank that, in a broad sense, includes a photomask blank having an opaque film formed on a substrate and a phase shift mask blank formed with a phase shift film having a phase shift function on a substrate.

This invention has been made for accomplishing the foregoing object and the gist thereof is the following contents as recited in claims. The following (1) to (8) correspond to claims 1 to 8.

(1) An unnecessary-film removal apparatus for supplying a chemical solution only to an unnecessary portion of a film formed on a surface of a substrate including a peripheral portion thereof to thereby remove the unnecessary-film portion formed on the substrate, characterized by comprising:

substrate holding means for holding the substrate so as to allow in-plane rotation thereof;

chemical solution supply means for supplying the chemical solution;

a shield member covering the main surface of the substrate so as to form a constant clearance with respect to the main surface of the substrate in a removal area of the main surface of the substrate and form a space larger than the clearance in a non-removal area of the main surface of the substrate, the clearance being set to a size that allows the chemical solution to enter the clearance and to spread only in the clearance; and

a chemical solution guide member located outside the shield member so as to form a flow path for the chemical solution cooperatively with the shield member;

the shield member and the chemical solution guide member being disposed so as to be rotatable along with the substrate holding means.

According to this accomplishing means, by providing the chemical solution guide member forming the flow path for the chemical solution cooperatively with the shield member, the clearance between the shield member and the chemical solution guide member and the flow rate of the chemical solution are adjusted while the clearance between the substrate and the shield member is maintained at the size that allows the chemical solution to enter the clearance and spread only in the clearance, so that the chemical solution supply amount to the unnecessary portion (removal area) of the film formed on the surface of the substrate can be sufficient as required and is controllable. Therefore, it is possible to securely prevent occurrence of the residue caused by a shortage of the chemical solution supply amount. Since the surface tension of the chemical solution acts in the clearance formed between the substrate and the shield member in the removal area of the main surface of the substrate, the chemical solution is filled (supplied) in the clearance. However, the chemical solution is not supplied into the space formed in the non-removal area of the main surface of the substrate because the surface tension of the chemical solution does not act in the space.

Herein, the peripheral portion of the substrate in this invention represents an area including the vicinity of a chamfered face in the main surface of the substrate, a side surface (end surface) of the substrate, a chamfered face provided between the side surface and main surface of the substrate, and further the vicinity of a chamfered face in the back surface of the substrate.

The chemical solution in this invention represents a solvent that dissolve the unnecessary film. For example, when a resist is the unnecessary film, it represents an organic solvent, a developer, or the like and, when an opaque film is the unnecessary film, it represents an etching solution that dissolves the opaque film, or the like.

It is preferable that, in order to allow the chemical solution to be securely and wastelessly supplied to the peripheral portion of the substrate, the chemical solution guide member be provided outside the shield member so as to surround the substrate with a predetermined distance from the side surface of the substrate.

The shield member is provided with a constant distance from the main surface of the substrate and with a constant width in the area of the unnecessary film portion (removal area) formed on the main surface of the substrate and this distance is set to a value that allows the chemical solution, when supplied to the clearance formed by this distance, to be filled only in the clearance due to the surface tension thereof. Therefore, by adjusting the foregoing width, the removal area in the main surface of the substrate can be controlled.

Further, the following configuration being means of later-described (2), (3), or (4) may be added to this accomplishing means.

That is, an unnecessary-film removal apparatus according to (1), wherein the shield member is provided with distance adjusting members at three or more positions facing the main surface of the substrate such that the clearance is set to a size that allows the chemical solution to enter the clearance and spread only in the clearance, and arrangement positions of the distance adjusting members are set such that, when the arrangement positions are connected to each other with a straight line, they are not located on the straight line and, when the shield member is rotated with respect to the substrate by a predetermined angle about the center of the surface of the substrate, they do not overlap the arrangement positions of the distance adjusting members before rotation.

Further, an unnecessary-film removal apparatus according to (1), characterized in that the shield member is provided with distance adjusting members at three or more positions facing the main surface of the substrate such that the clearance is set to a size that allows the chemical solution to enter the clearance and spread only in the clearance, arrangement positions of the distance adjusting members are set such that, when the arrangement positions are connected to each other with a straight line, they are not located on the straight line, and a moving mechanism is provided in which the distance adjusting members each move in parallel to a side direction of the substrate by a predetermined amount.

Further, an unnecessary-film removal apparatus according to (1), wherein the substrate holding means has a plurality of substrate holding members so as to hold the substrate at a plurality of positions on a bottom surface and side surfaces of the substrate, and arrangement positions of the substrate holding members are set such that, when the substrate is rotated with respect to the substrate holding members by a predetermined angle, the arrangement positions of the substrate holding members do not overlap those before rotation.

(2) An unnecessary-film removal apparatus for supplying a chemical solution only to an unnecessary portion of a film formed on a surface of a substrate including a peripheral portion thereof to thereby remove the unnecessary-film portion, characterized by comprising;

substrate holding means for holding the substrate so as to allow in-plane rotation thereof;

chemical solution supply means for supplying the chemical solution; and

a shield member covering the main surface of the substrate so as to form a constant clearance with respect to the main surface of the substrate in a removal area of the main surface of the substrate and form a space larger than the clearance in a non-removal area of the main surface of the substrate;

the shield member being provided with distance adjusting members that are three or more in number and that face the main surface of the substrate such that the clearance is set to a size that allows the chemical solution to enter the clearance and spread only in the clearance;

arrangement positions of the distance adjusting members being set such that, when the arrangement positions are connected to each other with a straight line, they are not located on the straight line and, when the shield member is rotated with respect to the substrate by a predetermined angle about the center of the surface of the substrate, they do not overlap the arrangement positions of the distance adjusting members positioned before rotation;

the shield member being disposed so as to be rotatable along with the substrate holding means.

According to this accomplishing means, in the area of the unnecessary film portion, by rotating the shield member with respect to the substrate by the predetermined angle during the unnecessary-film removal process, it is possible to securely prevent the residue after the removal of the unnecessary film at the positions where the shield member contacts the main surface of the substrate.

Herein, the distance adjusting member may be made of any material as long as it has resistance to the chemical solution to thereby ensure the constant distance with respect to the main surface of the substrate. The distance adjusting member may be in the form of a convex portion (projection) mechanically formed on the surface of the shield member facing the main surface of the substrate or in the form of a string-like member (e.g. a resin thread) having resistance to the chemical solution.

The reason for providing the distance adjusting members at three or more positions is that the plane of the shield member facing the main surface of the substrate can be specified so that the distance between the main surface of the substrate and the plane of the shield member facing the main surface of the substrate can be set constant.

The arrangement positions of the distance adjusting members are adjusted according to the shape of the substrate. That is, in the case of the shape of the substrate being square, when the shield member is rotated with respect to the substrate by 90 degrees, 180 degrees, and 270 degrees about the center (rotation center) of the main surface of the substrate, it is required that the arrangement positions of the distance adjusting members do not overlap those before the rotation, while, in the case of the shape of the substrate being rectangular (excluding square), when the shield member is rotated with respect to the substrate by 180 degrees about the center of the surface of the substrate, it is required that the arrangement positions of the distance adjusting members do not overlap those before the rotation. That is, when the shield member is rotated with respect to the substrate at an angle that does not change the relative position between the substrate and the shield member before and after the rotation, it is required that the arrangement positions of the distance adjusting members do not overlap those before the rotation.

It is preferable that the foregoing clearance be set to a size that allows the chemical solution to enter the clearance and spread only in the clearance. That is, since the surface tension of the chemical solution acts in the clearance formed between the substrate and the shield member in the removal area of the main surface of the substrate, the chemical solution is filled (supplied) in the clearance. However, the chemical solution is not supplied into the space formed in the non-removal area of the main surface of the substrate because the surface tension of the chemical solution does not act in the space.

The shield member is provided with a constant distance from the main surface of the substrate and with a constant width in the area of the unnecessary film portion (removal area) formed on the main surface of the substrate and this distance is set to a value that allows the chemical solution, when supplied to the clearance formed by this distance, to be filled only in the clearance due to the surface tension thereof. Therefore, by adjusting the foregoing width, the removal area in the main surface of the substrate can be controlled.

The following configuration being means of aforementioned (1) or later-described (4) may be added to this accomplishing means.

That is, an unnecessary-film removal apparatus according to (2), characterized by comprising a chemical solution guide member located outside the shield member so as to form a flow path for the chemical solution cooperatively with the shield member, wherein the shield member and the chemical solution guide member are disposed so as to be rotatable along with the substrate holding means.

Further, an unnecessary-film removal apparatus according to (2), wherein the substrate holding means has a plurality of substrate holding members so as to hold the substrate at a plurality of positions on a bottom surface and side surfaces of the substrate, and arrangement positions of the substrate holding members are set such that, when the substrate is rotated with respect to the substrate holding members by a predetermined angle, the arrangement positions of the substrate holding members do not overlap those before rotation.

(3) An unnecessary-film removal apparatus for supplying a chemical solution only to an unnecessary portion of a film formed on a surface of a substrate including a peripheral portion thereof to thereby remove the unnecessary-film portion, characterized by comprising:

substrate holding means for holding the substrate so as to allow in-plane rotation thereof;

chemical solution supply means for supplying the chemical solution; and

a shield member covering the main surface of the substrate so as to form a constant clearance with respect to the main surface of the substrate in a removal area of the main surface of the substrate and form a space larger than the clearance in a non-removal area of the main surface of the substrate;

the shield member being provided with distance adjusting members that are three or more in number and that face the main surface of the substrate such that the clearance is set to a size that allows the chemical solution to enter the clearance and spread only in the clearance;

arrangement positions of the distance adjusting members being set such that, when the arrangement positions are connected to each other with a straight line, they are not located on the straight line;

a moving mechanism being provided in which the distance adjusting members each move in parallel to a side direction of the substrate by a predetermined amount;

the shield member being disposed so as to be rotatable along with the substrate holding means.

According to this accomplishing means, without rotating the shield member by the predetermined angle with respect to the substrate during the unnecessary-film removal process, it is possible to securely prevent the residue after the removal of the unnecessary film at the positions where the shield member contacts the main surface of the substrate in the area of the unnecessary portion (removal area).

As an example of the moving mechanism in which the distance adjusting members each move in parallel to the side direction of the substrate by the predetermined amount, it is preferably a mechanism in which each distance adjusting member has a spherical structure with a diameter of 0.1 mm and is adapted to move by an electric drive, an air cylinder, or the like to a place where no residue occurs, along a guide groove of the shield member provided so as to face the main surface of the substrate.

It is preferable that the foregoing clearance be set to a size that allows the chemical solution to enter the clearance and spread only in the clearance. The reason is as described before.

The following configuration being means of aforementioned (1) or later-described (4) may be added to this accomplishing means.

That is, an unnecessary-film removal apparatus according to (3), characterized by comprising a chemical solution guide member located outside the shield member so as to form a flow path for the chemical solution cooperatively with the shield member, wherein the shield member and the chemical solution guide member are disposed so as to be rotatable along with the substrate holding means.

Further, an unnecessary-film removal apparatus according to (3), wherein the substrate holding means has a plurality of substrate holding members so as to hold the substrate at a plurality of positions on a bottom surface and side surfaces of the substrate, and arrangement positions of the substrate holding members are set such that, when the substrate is rotated with respect to the substrate holding members by a predetermined angle, the arrangement positions of the substrate holding members do not overlap those before rotation.

(4) An unnecessary-film removal apparatus for supplying a chemical solution only to an unnecessary portion of a film formed on a surface of a substrate including a peripheral portion thereof to thereby remove the unnecessary-film portion, characterized by comprising;

substrate holding means for holding the substrate so as to allow in-plane rotation thereof;

chemical solution supply means for supplying the chemical solution; and

a shield member covering the main surface of the substrate so as to form a constant clearance with respect to the main surface of the substrate in a removal area of the main surface of the substrate and to form a space larger than the clearance in a non-removal area of the main surface of the substrate, the clearance being set to a size that allows the chemical solution to enter the clearance and to spread only in the clearance;

the substrate holding means having a plurality of substrate holding members so as to hold the substrate at a plurality of positions on a bottom surface and side surfaces of the substrate;

arrangement positions of the substrate holding members being set such that, when the substrate is rotated with respect to the substrate holding members by a predetermined angle, the arrangement positions of the substrate holding members do not overlap previous ones positioned before rotation;

the shield member being disposed so as to be rotatable along with the substrate holding means.

According to this accomplishing means, by rotating the substrate with respect to the substrate holding means by the predetermined angle during the unnecessary-film removal process, it is possible to securely prevent the residue after the removal of the unnecessary film at the positions where the substrate and the substrate holding members of the substrate holding means contact each other.

The arrangement positions of the substrate holding members are adjusted according to the shape of the substrate. That is, in the case of the shape of the substrate being square, when the substrate is rotated with respect to the substrate holding means by 90 degrees, 180 degrees, and 270 degrees about the center (rotation center) of the main surface of the substrate, it is required that the arrangement positions of the substrate holding members do not overlap those before the rotation, while, in the case of the shape of the substrate being rectangular (excluding square), when the substrate is rotated with respect to the substrate holding means by 180 degrees about the center of the surface of the substrate, it is required that the arrangement positions of the substrate holding members do not overlap those before the rotation. That is, when the substrate is rotated with respect to the substrate holding means at an angle that does not change the relative position between the substrate holding means and the substrate before and after the rotation, it is required that the arrangement positions of the substrate holding members do not overlap those before the rotation.

It is preferable that the foregoing clearance be set to a size that allows the chemical solution to enter the clearance and spread only in the clearance. The reason is as described before.

The following configuration being means of aforementioned (1), (2), or (3) may be added to this accomplishing means.

That is, an unnecessary-film removal apparatus according to (4), characterized by comprising a chemical solution guide member located outside the shield member so as to form a flow path for the chemical solution cooperatively with the shield member, wherein the shield member and the chemical solution guide member are disposed so as to be rotatable along with the substrate holding means.

Further, an unnecessary-film removal apparatus according to (4), wherein the shield member is provided with distance adjusting members at three or more positions facing the main surface of the substrate such that the clearance is set to a size that allows the chemical solution to enter the clearance and spread only in the clearance, and arrangement positions of the distance adjusting members are set such that, when the arrangement positions are connected to each other with a straight line, they are not located on the straight line and, when the shield member is rotated with respect to the substrate by a predetermined angle about the center of the surface of the substrate, they do not overlap the arrangement positions of the distance adjusting members before rotation.

Further, an unnecessary-film removal apparatus according to (4), characterized in that the shield member is provided with distance adjusting members at three or more positions facing the main surface of the substrate such that the clearance is set to a size that allows the chemical solution to enter the clearance and spread only in the clearance, arrangement positions of the distance adjusting members are set such that, when the arrangement positions are connected to each other with a straight line, they are not located on the straight line, and a moving mechanism is provided in which the distance adjusting members each move in parallel to a side direction of the substrate by a predetermined amount.

(5) An unnecessary-film removal method using the unnecessary-film removal apparatus according to (1), characterized by placing the substrate on the substrate holding means and supplying the chemical solution from the chemical solution supply means while integrally rotating the substrate, the shield member, and the chemical solution guide member so that the chemical solution is supplied only to the unnecessary portion of the film formed on the surface of the substrate including its peripheral portion through the flow path formed by the shield member and the chemical solution guide member, thereby removing the unnecessary film portion.

According to this accomplishing means, by providing the chemical solution guide member forming the flow path for the chemical solution cooperatively with the shield member, the clearance between the shield member and the chemical solution guide member and the flow rate of the chemical solution are adjusted while the clearance between the substrate and the shield member is maintained at the size that allows the chemical solution to enter the clearance and spread only in the clearance, so that the chemical solution supply amount to the unnecessary portion (removal area) of the film formed on the surface of the substrate can be sufficient as required and is controllable. Therefore, it is possible to securely prevent occurrence of the residue caused by a shortage of the chemical solution supply amount. Since the surface tension of the chemical solution acts in the clearance formed between the substrate and the shield member in the removal area of the main surface of the substrate, the chemical solution is filled (supplied) in the clearance. However, the chemical solution is not supplied into the space formed in the non-removal area of the main surface of the substrate because the surface tension of the chemical solution does not act in the space.

(6) An unnecessary-film removal method using the unnecessary-film removal apparatus according to (2), characterized by placing the substrate on the substrate holding means and supplying the chemical solution from the chemical solution supply means while integrally rotating the substrate and the shield member so that the chemical solution is supplied only to the unnecessary portion of the film formed on the surface of the substrate including its peripheral portion along an outer wall of the shield member, thereby removing the unnecessary film portion, and thereafter, rotating the shield member with respect to the substrate by the predetermined angle about the center of the main surface of the substrate and removing the unnecessary film portion formed at positions where the distance adjusting members before rotation and the substrate were in contact with each other.

According to this accomplishing means, in the area of the unnecessary film portion, by rotating the shield member with respect to the substrate by the predetermined angle during the unnecessary-film removal process, it is possible to securely prevent the residue after the removal of the unnecessary film at the positions where the shield member contacts the main surface of the substrate.

(7) An unnecessary-film removal method using the unnecessary-film removal apparatus according to (3), characterized by placing the substrate on the substrate holding members of the substrate holding means and supplying the chemical solution from the chemical solution supply means while integrally rotating the substrate and the shield member so that the chemical solution is supplied only to the unnecessary portion of the film formed on the surface of the substrate including its peripheral portion along an outer wall of the shield member, thereby removing the unnecessary film portion, and thereafter, rotating the substrate holding means with respect to the substrate by the predetermined angle about the center of the main surface of the substrate and removing the unnecessary film portion formed at positions where the substrate holding members before rotation and the substrate were in contact with each other.

According to this accomplishing means, by rotating the substrate with respect to the substrate holding means by the predetermined angle during the unnecessary-film removal process, it is possible to securely prevent the residue after the removal of the unnecessary film at the positions where the substrate and the substrate holding members of the substrate holding means contact each other.

The foregoing configuration of (7) is added to the configuration of (6). That is, it is preferable because, by rotating the shield member with respect to the substrate by the predetermined angle and, further, rotating the substrate with respect to the substrate holding means by the predetermined angle during the unnecessary-film removal process, it is possible to securely prevent the residue after the removal of the unnecessary film at the positions where the shield member contacts the main surface of the substrate and at the positions where the substrate and the substrate holding members contact each other.

(8) A photomask blank manufacturing method having a film forming process for forming a film such as an opaque film on an optically transparent substrate, the photomask blank manufacturing method characterized by comprising an unnecessary-film removal process for removing an unnecessary film formed at an unnecessary portion in the film forming process, by the use of the unnecessary-film removal method according to (5) to (7).

According to this accomplishing means, since the residue (e.g. resist residue) after the removal of the unnecessary film can be securely prevented, it is possible to prevent generation of dust from the peripheral portion of the substrate at the time of storage of the photomask blank, or the like.

The foregoing film such as the opaque film represents a thin film causing an optical change (light-shielding function or phase change) with respect to exposure light, a resist film, a functional film such as a conductive film or a protective film, or the like. The removal of the unnecessary film represents removing at least one of those films.

### BRIEF DESCRIPTION OF THE DRAWINGS

FIG. 1 is a sectional view showing a structure of an unnecessary-film removal apparatus of this invention in the state where a substrate with a resist is set in the unnecessary-film removal apparatus.

FIG. 2 is a detailed diagram of a contact portion between an inner cover member and the substrate, used in this invention.

FIG. 3 is a diagram for explaining arrangement positions of distance adjusting convex portions in an unnecessary-film removal method that rotates a cover member.

FIG. 4 is a diagram for explaining a method of moving distance adjusting convex portions in an unnecessary-film removal method that does not rotate a cover member.

FIG. 5 is a diagram for explaining a substrate holding stage and substrate holding members used in this invention.

FIG. 6 is a diagram for explaining a method of rotating the substrate holding stage used in this invention.

FIG. 7 is a diagram for explaining unnecessary-film removal processes (the case only by a chemical solution and the case of employing exposure and development treatments) of this invention.

FIG. 8 is a flowchart showing an Example of the unnecessary-film removal process in this invention.

FIG. 9 is a sectional view showing a structure of a conventional unnecessary-film removal apparatus.

FIG. 10 is a sectional view showing a modification of an unnecessary-film removal apparatus of this invention.

FIG. 11 is a diagram showing as an example a convex portion moving mechanism in this invention.

### BEST MODE FOR CARRYING OUT THE INVENTION

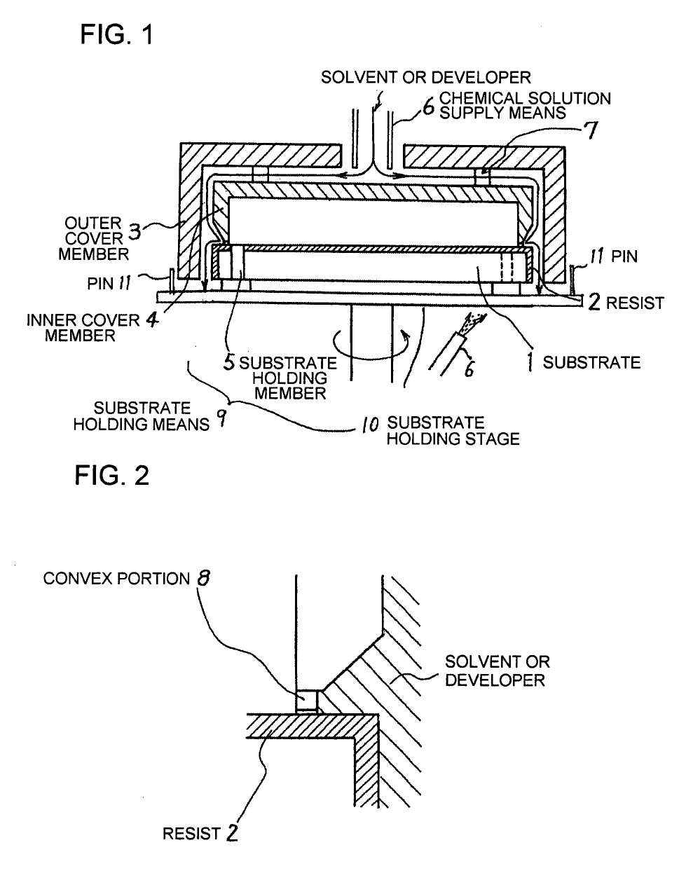

Embodiments of this invention will be described in detail with reference to FIGS. 1 to 8.

FIG. 1 is a sectional view showing a structure of an unnecessary-film removal apparatus of this invention in the state where a substrate with a resist is set in the unnecessary-film removal apparatus.

In FIG. 1, a substrate 1 is a photomask blank in which an opaque film containing chromium as a main component is formed on the surface of a transparent substrate (152.4 mm×152.4 mm×6.35 mm) made of synthetic quartz glass and, further, a resist 2 is formed on the opaque film to a desired film thickness by a spin coating method or the like.

Herein, the resist 2 should be primarily formed only in a desired effective area on the surface of the substrate 1. However, the resist 2 is also formed at the peripheral portion on the surface of the substrate 1, at the side portion of the substrate and even at the back portion of the substrate, depending on conditions, where the resist does not primarily need to be formed. An unnecessary-film removal method and apparatus according to this invention are a method and apparatus for removing such an unnecessary film.

### First Embodiment

As shown in FIG. 1, the unnecessary-film removal apparatus of the first embodiment comprises substrate holding means 9 for holding the substrate 1 so as to allow in-plane rotation thereof, chemical solution supply means 6 for supplying a chemical solution that serves to remove an unnecessary film portion formed on the substrate 1, an inner cover member 4 serving as a shield member provided so as to prevent the chemical solution from being supplied to the main surface of the substrate except the unnecessary film portion, and an outer cover member 3 serving as a chemical solution guide member forming a flow path for the chemical solution by cooperating with the inner cover member 4.

The substrate holding means 9 comprises a plurality of substrate holding members 5 provided on a substrate holding stage 10, serving also as a spin chuck, so as to hold the substrate 1 in parallel at a plurality of positions on a bottom surface and side surfaces of the substrate 1. In order to stably hold the substrate 1 during rotation thereof, each substrate holding member 5 has a shape so as to provide surface contact or line contact with the bottom surface or side surface of the substrate.

Each substrate holding member 5 has, for example, a shape of a single cylinder or a shape of two piled cylinders having different sizes. When the substrate 1 is square, the cylindrical substrate holding members 5 are provided on the substrate holding stage 10 such that the substrate holding members 5 (cylinders) are disposed at two positions at each of both ends in a diagonal direction of the substrate 1 so as to sandwich a corner therebetween, thereby determining the position of the substrate 1 through surface contact and line contact with a bottom surface and side surface of each substrate holding member 5, while the substrate holding member 5 (cylinder) is disposed at a single position at each of both ends in the other diagonal direction so as to hold the substrate in parallel through surface contact between the bottom surface of the substrate and an upper surface of each substrate holding member 5. The inner cover member 4 has a shape so as to cover the main surface of the substrate 1 from above. The shape is such that the major part of the inner cover member 4 from the center portion of the substrate to its periphery is a flat portion that is substantially flat and peripheral ends of the flat portion are bent substantially perpendicularly downward to thereby form a side portion. When provided on the main surface of the substrate 1, the inner cover member 4 is fixed so that a constant clearance is formed at a bottom surface of the side portion of the inner cover member. In this case, the outer side of the bottom surface of the side portion of the inner cover member 4 becomes an unnecessary portion (removal area) on the main surface of the substrate. On the other hand, a space greater than the dimension of the foregoing clearance is formed at the flat portion, i.e. other than the side portion, of the inner cover member 4, thereby defining a non-removal area. There is no particular limitation to a fixing manner for forming the constant clearance between the inner cover member and the substrate. The inner cover member may be provided with later-described distance adjusting members at the bottom surface of the side portion and placed on the main surface of the substrate 1 or fixedly suspended from above the main surface of the substrate. By giving the foregoing shape to the inner cover member 4, when the chemical solution is supplied to the clearance formed between the bottom surface of the side portion of the inner cover member 4 and the main surface of the substrate, the surface tension of the chemical solution acts so that although the clearance is filled with the chemical solution, the chemical solution is not supplied into the space formed at the non-removal area of the main surface of the substrate because the surface tension of the chemical solution does not act in the space.

Further, in order to sufficiently supply the chemical solution to the unnecessary film portion at the clearance and on the side surfaces of the substrate, the outer cover member 3 is provided so as to cover the inner cover member 4 and the side surfaces of the substrate 1. The outer cover member 3 and the inner cover member 4 are fixed together by connecting members 7 so that a certain clearance is formed between the outer cover member 3 and the inner cover member 4 and serves as a flow path for the chemical solution. By adjusting the sectional area of this flow path and the flow rate of the chemical solution, the supply amount of the chemical solution to the unnecessary film portion can be adjusted. In order that the chemical solution supplied by the chemical solution supply means 6 is guided to the unnecessary film portion of the substrate 1 along the outer periphery of the inner cover member 4, the outer cover member 3 is provided at its upper part with an opening portion serving as a supply port for the chemical solution from the chemical solution supply means 6.

The substrate holding stage 10 is provided with pins 11 for positioning so that the rotation center of the substrate holding means 9 and the rotation center of the inner cover member 4 and outer cover member 3 coincide with each other. (Since the substrate 1 is held by the substrate holding means 9, the rotation centers of the substrate 1 and the inner cover member 4 and outer cover member 3 resultantly coincide with each other.)

The unnecessary film formed on the surface of the substrate is removed by the chemical solution supplied from the chemical solution supply means 6. The chemical solution supply means 6 are, for example, of a nozzle shape and are disposed at the opening portion provided at the upper part of the outer cover member 3 and on the back side of the substrate 1, respectively. The chemical solution supply means 6 disposed on the back side of the substrate 1 serves to remove the unnecessary film mainly adhering to the back surface of the substrate 1. The chemical solution is, for example, a solvent such as acetone or a developer such as TMAH (tetramethylammonium hydroxide).

The chemical solution supplied from the chemical solution supply means 6 flows along the outer periphery of the inner cover member 4 through the flow path formed between the inner cover member 4 and the outer cover member 3 and is supplied to the unnecessary film portion formed on the surface of the substrate. Since the substrate 1 is held by the substrate holding means 9 and further the substrate holding means 9 and the outer cover member 3 are fixed together by the pins 11 provided on the substrate holding stage 10 of the substrate holding means 9 (the outer cover member 3 and the inner cover member 4 are fixed together by the connecting members 7), the substrate 1, the inner cover member 4, and the outer cover member 3 rotate as one unit, so that the unnecessary film dissolved by the chemical solution is removed outward by centrifugal force. When supplying the chemical solution to the unnecessary film portion of the substrate 1, it is preferable that the substrate 1, the inner cover member 4, and the outer cover member 3 be rotating because the chemical solution can be uniformly supplied to the peripheral portion of the substrate 1.

FIG. 10 is a sectional view showing a modification of the unnecessary-film removal apparatus of the first embodiment.

In FIG. 10, covering the upper side of a substrate with a resist (mask blank) with an inner cover member 4 serving as a shield member is the same as the foregoing first embodiment in that, but difference exists in that an outer cover member 3 serving as a chemical solution guide member is placed on a substrate holding stage 10 so as to be disposed outside to thereby surround the side portion of the inner cover member 4 and the side portion of the substrate 1. In order to sufficiently supply a chemical solution into a flow path between the inner cover member 4 and the outer cover member 3, the outer periphery of the inner cover member 4 has an obliquely inclined shape.

The chemical solution supplied from a chemical solution supply means 6 is supplied into the flow path between the inner cover member 4 and the outer cover member 3 through the inclined surface formed at the outer periphery of the inner cover member 4 so as to be supplied to an unnecessary film portion formed on the surface of the substrate. By integral rotation of the substrate 1, the inner cover member 4, and the outer cover member 3, the unnecessary film dissolved by the chemical solution is removed outward by centrifugal force.

FIG. 2 is a detailed diagram of a contact portion between the inner cover member 4 and the substrate, showing one example for forming the constant clearance between the main surface of the substrate and the inner cover member in the unnecessary-film removal area of the main surface of the substrate.

On the bottom surface of the side portion of the inner cover member 4 (the unnecessary-film removal area of the main surface of the substrate) are provided convex portions 8 serving as distance adjusting members for adjusting the clearance between the inner cover member 4 and the surface of the substrate (resist). By the convex portions 8, the distance between the bottom surface of the side portion of the inner cover member 4 and the surface of the resist 2 is maintained at a constant distance of about 0.1 mm. This distance is set so that the chemical solution can enter only the clearance between the bottom surface of the side portion of the inner cover member 4 and the surface of the resist 2 due to its surface tension. As a result, it is possible to prevent invasion of the chemical solution into the desired effective area where the formed resist film should not be damaged.

The convex portions 8 are provided at three or more positions on the bottom surface of the side portion of the inner cover member.

The reason for the three or more positions is that a plane can be specified with the three or more positions and thus the clearance between the bottom surface of the side portion of the inner cover member 4 and the surface of the substrate can be determined.

Each convex portion 8 may be formed by machining the bottom surface of the side portion of the inner cover member 4 or by attaching another member of a constant height to the bottom surface of the side portion of the inner cover member 4. For example, each convex portion 8 can be formed by a string-like member (e.g. a resin thread) having resistance to the chemical solution. This is because the resin thread is easy to obtain and, further, the dimension of the clearance between the inner cover member 4 and the resist 2 can be easily held constant by interposing it between the bottom surface of the side portion of the inner cover member 4 and the surface of the resist 2. The thickness of the thread, i.e. the dimension d1 of the clearance between the bottom surface of the side portion of the inner cover member 4 and the surface of the resist 2, is set to a value that allows the chemical solution to pass therethrough, when supplied to the clearance, to be filled only in the clearance without flowing out to the center side of the substrate from the clearance due to its surface tension. Preferably, d1 is set to 0.05 to 3 mm. This is because less than 0.05 mm of the clearance makes it difficult to sufficiently supply the chemical solution to the clearance, so that there is a case where the clearance is not filled with the chemical solution, which brings about occurrence of those portions that cannot be removed, or there is a case where a boundary between the removal portion and the other portion becomes jagged. Further, this is because greater than 3 mm of clearance brings about inaction of the surface tension and, as a result, the chemical solution flows toward the center side of the substrate. This removes the area where the resist film should primarily be formed (non-removal area).

### Second Embodiment

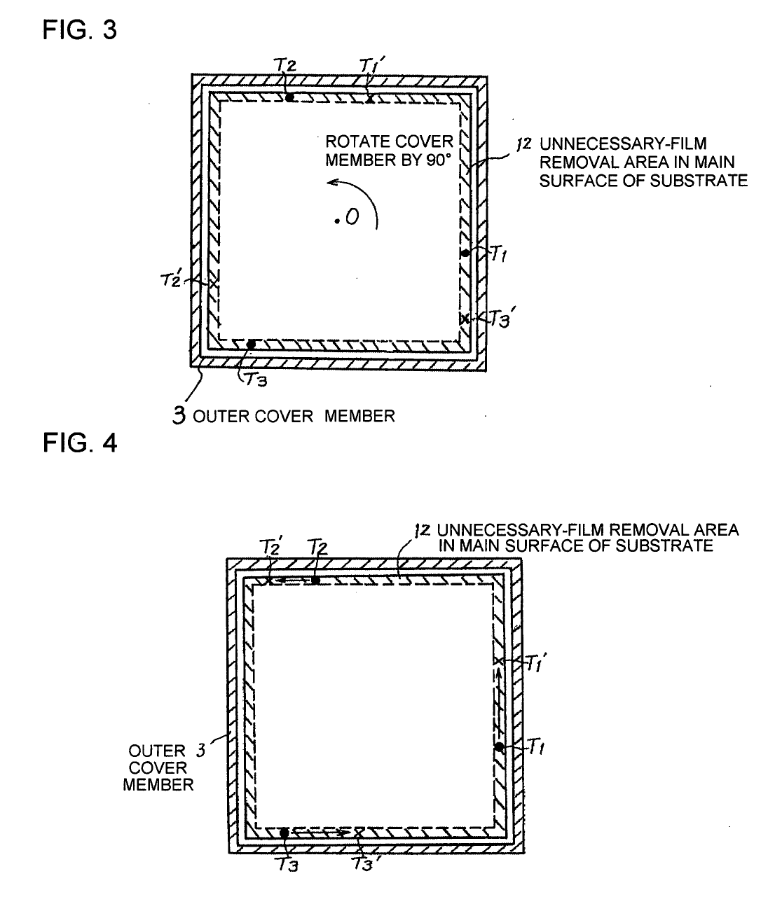

FIG. 3 is a diagram for explaining arrangement positions of distance adjusting members being the main part of an unnecessary-film removal apparatus and unnecessary-film removal method of the second embodiment. In the example shown in FIG. 3, there is shown a case of using the inner cover member 4 and the outer cover member 3 (when explaining FIG. 3, the inner cover member 4 and the outer cover member 3 will be referred to collectively as a cover member) in the unnecessary-film removal apparatus of the foregoing first embodiment. However, an unnecessary-film removal apparatus is not limited thereto and may have only the inner cover member 4.

In FIG. 3, ● marks (T1 to T3) represent positions where the convex portions 8 before carrying out an unnecessary-film removal process contact an unnecessary-film removal area 12 in the main surface of the substrate. When the unnecessary film formed at the peripheral portion of the substrate is removed in the state where the convex portions 8 contact the removal area 12 at the ● mark positions, resist residue occurs because the chemical solution is not supplied to the ● mark positions. In order to remove the resist residue remaining at the ● mark positions, the cover member is rotated counterclockwise by 90 degrees with respect to the substrate to thereby locate the convex portions 8 at positions of x marks (T1′ to T3′) and then the unnecessary-film removal process is restarted, so that it is possible to remove the resist residue remaining at the positions where the convex portions 8 before the rotation were in contact with the substrate. That is, in the unnecessary-film removal apparatus and unnecessary-film removal method of the second embodiment, by setting the arrangement positions of the distance adjusting members such that, when the cover member is rotated with respect to the substrate by a predetermined angle about the center of the surface of the substrate, the arrangement positions of the distance adjusting members do not overlap those before the rotation, the residue after the removal of the unnecessary film can be securely prevented. In this embodiment, the cover member is rotated by 90 degrees with respect to the substrate. However, when the substrate is square, the cover member may also be rotated by 180 degrees or 270 degrees. Further, the cover member may be fixed while the substrate may be rotated.

### Third Embodiment

FIG. 4 is a diagram for explaining a method of moving distance adjusting members being the main part of an unnecessary-film removal apparatus and unnecessary-film removal method of the third embodiment. In the example shown in FIG. 4, there is shown a case of using the inner cover member 4 and the outer cover member 3 (when explaining FIG. 4, the inner cover member 4 and the outer cover member 3 will be referred to collectively as a cover member) in the unnecessary-film removal apparatus of the foregoing first embodiment. However, an unnecessary-film removal apparatus is not limited thereto and may have only the inner cover member 4.

In FIG. 4, ● marks (T1 to T3) represent positions where the convex portions 8 before carrying out an unnecessary-film removal process contact an unnecessary-film removal area 12 in the main surface of the substrate. When the unnecessary film formed at the peripheral portion of the substrate is removed in the state where the convex portions 8 contact the removal area 12 at the ● mark positions, resist residue occurs because the chemical solution is not supplied to the ● mark positions. In order to remove the resist residue remaining at the ● mark positions, the positions of the convex portions 8 are moved to x marks (T1′ to T3′) and then the unnecessary-film removal process is restarted, so that it is possible to remove the resist residue remaining at the positions where the convex portions 8 before the rotation were in contact with the substrate. That is, in the unnecessary-film removal apparatus and unnecessary-film removal method of the third embodiment, the arrangement positions of the distance adjusting members are each adapted to move by a predetermined amount in parallel to a side direction of the substrate so that the residue after the removal of the unnecessary film can be securely prevented.

Although a moving mechanism for the convex portions 8 is not questioned, it is preferably a mechanism in which, for example, each convex portion 8 has a spherical structure of about 0.1 mm and is adapted to move by an air cylinder or the like in parallel to a side direction of the substrate 1 along a groove formed on the bottom surface of the side portion of the inner cover member 4.

FIG. 11 is a diagram showing as an example a convex portion moving mechanism in this invention.

In FIG. 11, a distance adjusting member (convex portion) can move in parallel to a side direction of the substrate by a piston cylinder and an elastic member (spring) attached to an inner cover member 4 covering the upper surface of the substrate.

### Fourth Embodiment

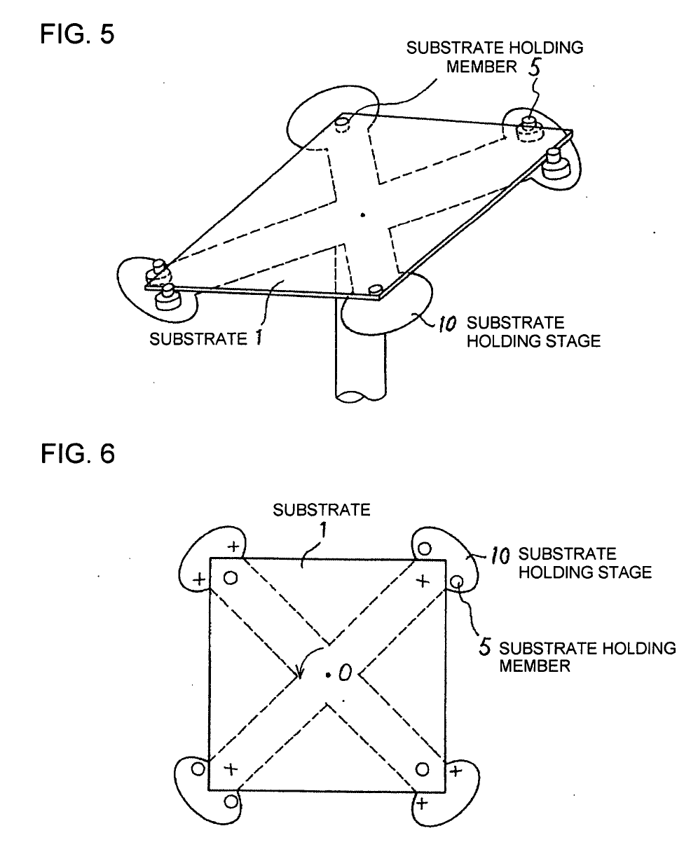

FIG. 5 is a diagram for explaining a substrate holding stage and substrate holding members in a substrate holding means being the main part of an unnecessary-film removal apparatus and unnecessary-film removal method of the fourth embodiment.

In FIG. 5, a single substrate holding member 5 (or a plurality thereof) is disposed at each of both ends in a diagonal direction of a substrate holding stage 10 serving also as a spin chuck so as to hold the side surface and back surface (or chamfered face on the back side) of the substrate 1 and a single substrate holding member 5 is disposed at each of both ends in the other diagonal direction so as to hold (support) the back surface of the substrate 1. The substrate 1 is fixed to the substrate holding stage 10 by these substrate holding members 5. The substrate holding stage 10 is rotated by a non-illustrated driving device along with the substrate 1 and the cover member while the chemical solution is supplied from the chemical solution supply means 6, so that the chemical solution is supplied to the peripheral portion of the substrate to thereby remove the unnecessary film.

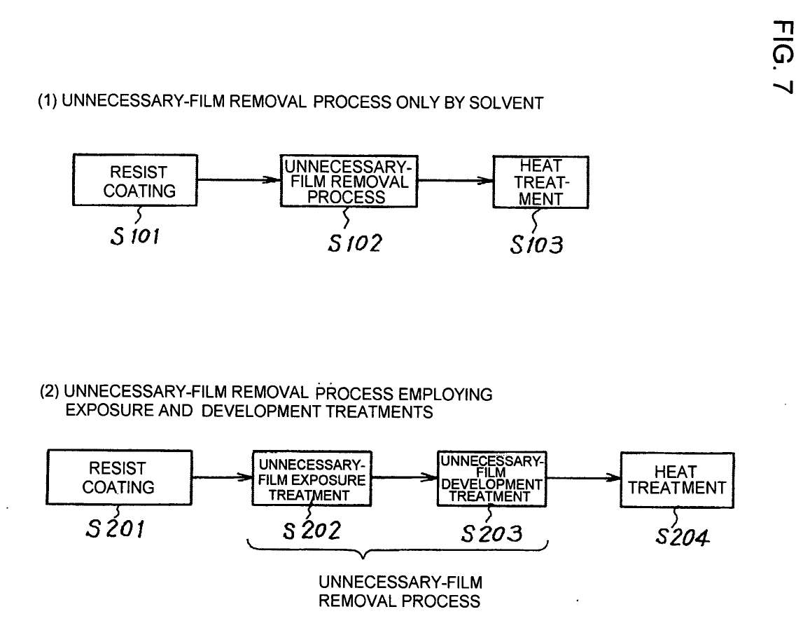

FIG. 6 is a diagram for explaining arrangement positions of the substrate holding means and a method of rotating the substrate holding means being the main part of the unnecessary-film removal apparatus and unnecessary-film removal method of the fourth embodiment.

In FIG. 6, ∘ marks represent positions of the substrate holding members 5 before carrying out an unnecessary-film removal process. When the unnecessary film formed at the peripheral portion of the substrate is removed in the state where the substrate holding members 5 contact the unnecessary-film removal area (the side surface and back surface of the substrate) at the ∘ mark positions, resist residue occurs because the chemical solution is not supplied to the ∘ mark positions contacting the substrate 1. In order to remove the resist residue remaining at the ∘ mark positions, the substrate holding means is rotated counterclockwise by 90 degrees with respect to the substrate to thereby locate the substrate holding members 5 at positions of x marks and then the unnecessary-film removal process is restarted, so that it is possible to remove the resist residue remaining at the positions where the substrate holding members 5 before the rotation were in contact with the substrate. That is, in the unnecessary-film removal apparatus and unnecessary-film removal method of the fourth embodiment, by setting the arrangement positions of the substrate holding members such that, when the substrate holding means is rotated with respect to the substrate by a predetermined angle about the center of the surface of the substrate, the arrangement positions of the substrate holding members do not overlap those before the rotation, the residue after the removal of the unnecessary film can be securely prevented. In this embodiment, the substrate holding means (the positions of the substrate holding members) is rotated by 90 degrees with respect to the substrate. However, when the substrate is square, the substrate holding means (the positions of the substrate holding members) may also be rotated by 180 degrees or 270 degrees. Further, the substrate holding means (the positions of the substrate holding members) may be fixed while the substrate may be rotated.

### EXAMPLE 1

FIG. 7, (1) is a diagram for explaining an unnecessary-film removal process (the case only by the chemical solution) of this invention in a photomask blank manufacturing method, wherein part of the photomask blank manufacturing process after formation of a thin film such as an opaque film is extracted. In the case of adopting the removal of the unnecessary resist film only by the chemical solution, the main process after the formation of the thin film such as the opaque film comprises processes of resist coating (S101), unnecessary-film removal (S102), and heat treatment (S103).

At first, a resist is spin-coated on the main surface of a substrate formed with a thin film such as an opaque film (S101). Thereafter, the substrate with the resist subjected to the resist coating is placed on the substrate holding stage of the foregoing unnecessary-film removal apparatus. The type of the resist used herein is ZEP7000 (manufactured by ZEON Corporation).

Then, the substrate with the resist placed on the substrate holding stage is covered with the cover member composed of the outer cover member serving as a chemical solution guide member and the inner cover member serving as a shield member provided so as to prevent the chemical solution from being supplied to other than the unnecessary portion. While the substrate with the resist and the cover member are rotated together at a predetermined rotation speed, an organic solvent (acetone) is supplied to the unnecessary resist film portion at the peripheral portion of the substrate so that the unnecessary film at the peripheral portion of the substrate is removed. Then, by stopping the supply of the organic solvent and rotating the substrate with the resist and the cover member at a rotation speed higher than the predetermined rotation speed, the portion where the unnecessary film was removed is rotated to dry so that the removal of the unnecessary resist film at the peripheral portion of the substrate is completed (S102).

Thereafter, by applying heat treatment (S103), it is possible to obtain a photomask blank having the resist formed only in the desired effective area at the center of the substrate.

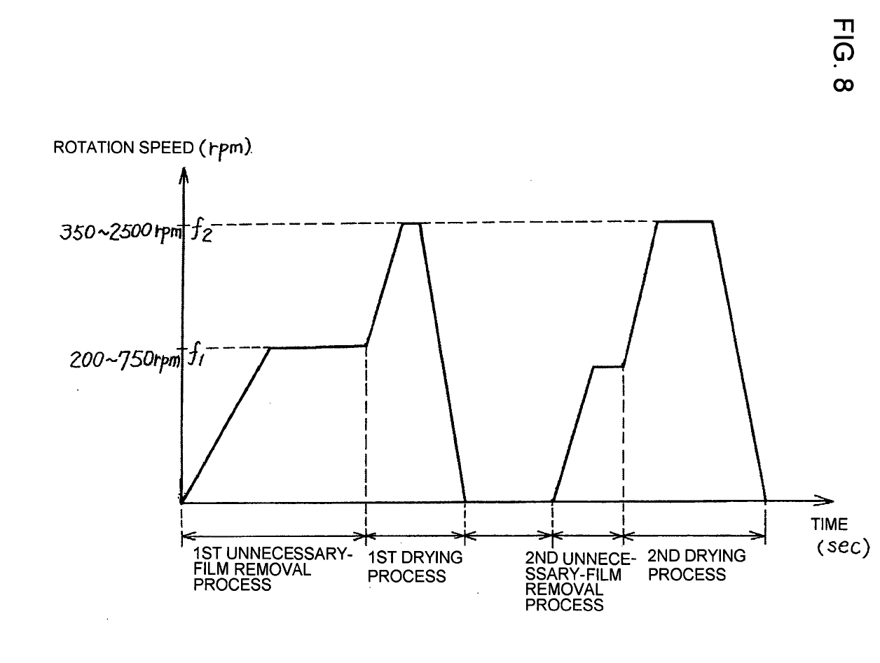

Herein, FIG. 8 is a flowchart for showing details of the unnecessary-film removal process in this invention. At first, a substrate with a resist after coating of the resist was placed on the substrate holding stage and covered with the foregoing cover member.

Then, the substrate holding stage was rotated at a rotation speed f1 (adjusted in the range of 200 to 750 rpm (500 rpm in this Example)) and, simultaneously, the chemical solution was supplied while finely adjusting the supply amount from the chemical solution supply means (nozzle). The substrate holding stage was rotated for a rotation time t1 (adjusted in the range of 5 to 300 seconds (30 seconds in this Example)). By this, the chemical solution dissolved and removed the unnecessary film portion at the peripheral portion of the substrate (first unnecessary-film removal process).

Then, the supply of the chemical solution from the chemical solution supply means (nozzle) was stopped and, subsequently, the substrate holding stage was rotated at a rotation speed f2 (adjusted in the range of 350 to 2500 rpm (2000 rpm in this Example)). By this, the portion where the unnecessary film was removed was dried (first drying process).

At this stage, invasion of the chemical solution was avoided at positions where three distance adjusting members (convex portions) provided at the inner cover member were in contact with the substrate with the resist, while the resist remained as a residue at those positions.

Therefore, then, after detaching the cover member, the cover member was placed again at a position to which the substrate with the resist and the substrate holding stage were rotated together by 90 degrees. Through this operation, the positions where the distance adjusting members (convex portions) and the substrate with the resist were in contact with each other before rotating the cover member relative to the substrate with the resist were changed from the positions where they contact each other after rotating the cover member relative to the substrate with the resist, so that it is possible to securely remove the resist residue.

Further, in order to remove resist residue at positions where the substrate holding members and the substrate with the resist are in contact with each other, the substrate with the resist and the substrate holding stage are rotated together by 90 degrees relative to the cover member after raising the cover member, then the substrate is raised and only the substrate holding stage is rotated by 90 degrees relative to the substrate with the resist, and then the substrate with the resist and the cover member are placed again on the substrate holding stage. Through this operation, the positions where the distance adjusting members and the substrate with the resist were in contact with each other before the rotation and the positions where the substrate holding members and the substrate with the resist were in contact with each other before the rotation all differ from the positions where they contact each other after such operation, so that it is possible to securely remove the resist residue at all those positions.

Then, chemical solution supply, unnecessary-film removal, and drying are carried out again according to the procedure described above (second unnecessary-film removal process and second drying process).

By carrying out heat treatment and so on after the resist coating and the unnecessary-film removal process, it was possible to obtain a photomask blank having the resist film formed only in the desired effective area at the center portion of the substrate because the unnecessary resist residue does not remain at the positions contacting the cover member and the substrate holding members.

### EXAMPLE 2

FIG. 7, (2) is a diagram for explaining an unnecessary-film removal process (the case of executing exposure and development treatments) of this invention in a photomask blank manufacturing method, wherein illustration is selectively made only about the photomask blank manufacturing process after formation of a thin film such as an opaque film. In the case of adopting the removal of the unnecessary resist film by the exposure and development treatments, the main process after the formation of the thin film such as the opaque film comprises processes of resist coating (S201), unnecessary-film exposure treatment (S202), unnecessary-film development treatment (S203), and heat treatment (S204).

At first, a resist is spin-coated on the main surface of a substrate formed with a thin film such as an opaque film (S201). The type of the resist used herein is a positive high-polymer electron-beam writing exposure resist and is ZEP7000 (manufactured by ZEON Corporation) slightly sensitive also to far-infrared radiation.

Thereafter, the substrate with the resist subjected to the resist coating is exposed only at its unnecessary film portion according to a later-described exposure method (S202).

The substrate with the resist subjected to the exposure is placed on the substrate holding stage of the foregoing unnecessary-film removal apparatus. Then, the substrate with the resist placed on the substrate holding stage is covered with the cover member composed of the outer cover member serving as a chemical solution guide member and the inner cover member serving as a shield member provided so as to prevent the chemical solution from being supplied to other than the unnecessary portion. While the substrate with the resist and the cover member are being rotated together at a predetermined rotation speed, a standard developer (ZED400 (manufactured by ZEON Corporation)) is supplied to the unnecessary resist film portion at the peripheral portion of the substrate and then a standard rinse solution ZMD-B is immediately supplied in place of the developer, thereby rinsing the developing removal portion. Then, by stopping the supply of the rinse solution and rotating the substrate with the resist and the cover member at a rotation speed higher than the predetermined rotation speed, the portion where the unnecessary film was removed is rotated to dry so that the removal of the unnecessary resist film at the peripheral portion of the substrate is completed (S203).

The foregoing exposure method for exposing only the unnecessary film portion was carried out in the following manner. As an exposure light source, a mercury lamp was used which has a quartz fiber light guide (10 mmφ) that was mounted at its tip with a condenser lens having a focal length of 10 mm. A stencil mask having an opening portion of 3 mm×3 mm square was located at the focal portion such that the stencil mask was disposed at a position of 3 mm from the upper surface of the substrate with about 2 mm of the stencil mask (exposure window) overlapping the substrate from its end toward its center.

Then, the exposure light source was turned on and, simultaneously, the substrate with the resist was moved right under the exposure window at a speed of about 10 mm per second by the use of a scanning means. After finishing the exposure of two sides of the substrate with the resist, the substrate with the resist was rotated by 90 degrees to expose the other two sides in the same manner. By exposing all the four sides of the substrate with the resist, the exposure treatment of only the unnecessary film portion was carried out.

The foregoing unnecessary-film development treatment was carried out according to the flowchart shown in FIG. 8 under the same treatment conditions (rotation speed, rotation time) as those in Example 1 except that the developer was used instead of the organic solvent.

Subsequently, in order to remove resist residue at positions where the cover member and the substrate with the resist were in contact with each other and at positions where the substrate holding members and the substrate with the resist were in contact with each other in the unnecessary-film development process (first unnecessary-film removal process, first drying process), the substrate with the resist and the substrate holding stage were rotated together by 90 degrees relative to the cover member after raising the cover member, then the substrate was raised and only the substrate holding stage was rotated by 90 degrees relative to the substrate with the resist, then the substrate with the resist and the cover member were placed again on the substrate holding stage, and then a second unnecessary-film removal process and a second drying process were carried out.

Thereafter, by applying heat treatment (S103), it is possible to obtain a photomask blank having the resist formed only in the desired effective area at the center of the substrate.

As a result, like in Example 1, since the unnecessary resist residue does not remain at the positions where the distance adjusting members and the substrate holding members are in contact with the substrate with the resist in the unnecessary-film development process, it is possible to obtain the photomask blank having the resist film formed only in the desired effective area at the center portion of the substrate.

### COMPARATIVE EXAMPLE

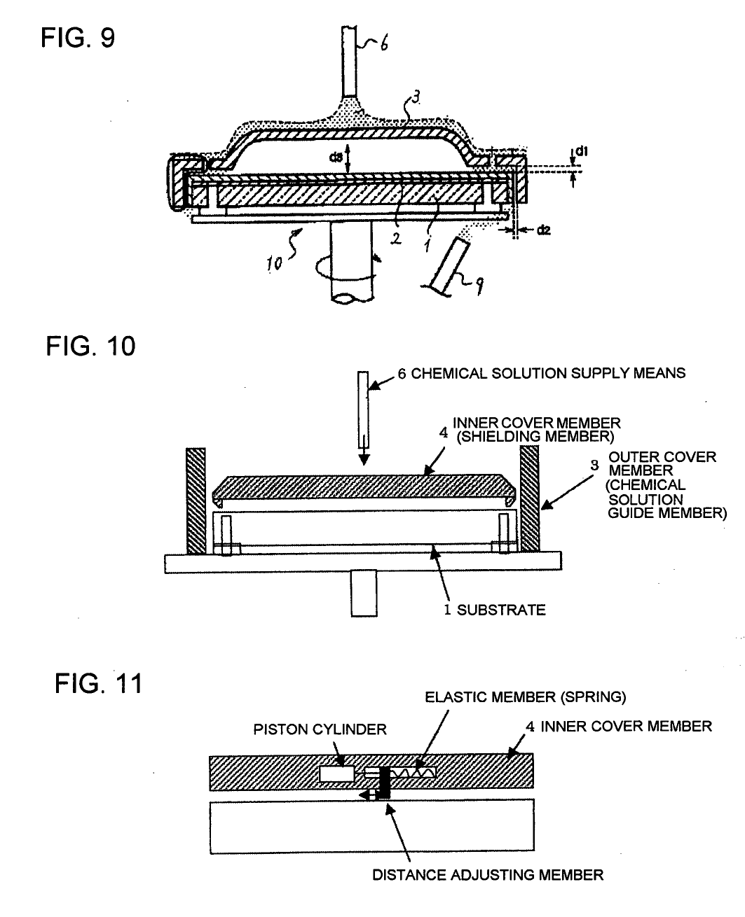

By the use of an unnecessary-film removal apparatus of FIG. 9, an unnecessary film at the peripheral portion of a substrate with a resist having the resist coated on the main surface of the substrate formed with a thin film such as an opaque film was removed. As the resist, use was made of ZEP7000 (manufactured by ZEON Corporation) being the same positive high-polymer electron-beam writing resist as in Examples 1 and 2. A flowchart of an unnecessary-film removal process was such that an unnecessary film was removed like in Example 1 except that only the first unnecessary-film removal process and the first drying process in FIG. 8 were carried out. As a result, although the unnecessary-film removal apparatus of FIG. 9 is configured such that a solvent is supplied through holes formed in a shield member and located over the peripheral portion of the substrate, since no outer cover member is provided, much of the solvent supplied from a chemical solution supply means is difficult to flow into the holes formed in the shield member (i.e. a clearance formed between the shield member and the substrate) due to centrifugal force generated by rotation. As a result, because of a shortage of the supply of the solvent, non-removable portions were generated so that a boundary between the removed portion and the other portion became jagged. String-like members (threads) were used as members for adjusting the distance between the cover member and the surface of the substrate with the resist. Unnecessary resist residue occurred at positions where the string-like members (threads) were in contact with the substrate with the resist and at positions where substrate holding members were in contact with the substrate with the resist.

As described above, as shown in Examples 1 and 2 and Comparative Example, since there is no resist residue at the peripheral portion of the substrate after the removal of the unnecessary film in Examples 1 and 2, it is possible to prevent generation of a defect on the surface of the photomask blank caused by stripping of resist residue. On the other hand, in the case of Comparative Example, since the resist residue exists at the peripheral portion of the substrate after the removal of the unnecessary film, it is not possible to prevent that the resist residue is stripped to fall off and adheres to the photomask blank itself or various processing apparatuses, thereby finally causing defects of or a reduction in production yield of photomasks being the products using the photomask blank as a feed material.

Herein, in the foregoing Examples, the rotation of the cover member and/or the substrate holding members relative to the substrate with the resist is once. However, when carrying out the unnecessary film removal process and the drying process three times or more, the rotation process of the cover member and/or the substrate holding members may be implemented twice or more.

In the foregoing Example 1, acetone is used as the solvent for dissolving the resist. However, the solvent is not limited to acetone and may be any solvent as long as it can dissolve and remove the unnecessary film, such as a solvent that can dissolve the resist.

A material of the cover member (the inner cover member serving as the shield member, the outer cover member serving as the chemical solution guide member) may be any material that has low a heat transfer characteristic, resistance to the chemical solution, and a predetermined mechanical strength. For example, there can be cited a resin material, a glass material, a ceramic material, a composite material thereof, or the like. Among them, the resin material is preferable because heat is relatively difficult to transfer, the processing is easy, and a reduction in weight is easy. It is preferable that the portion, covering the area other than the unnecessary film portion of the surface of the substrate, of the cover member be made of the foregoing material.

In the foregoing Examples 1 and 2, the positive high-polymer electron-beam writing exposure resist is used. However, the resist is not limited to this and it is needless to say that a negative type, a chemically amplified resist, or a laser writing exposure resist is also applicable.

Further, in the foregoing Examples, the description has been made about the example of application to the case of the photomask blank manufacturing method that forms the resist film on the opaque film. However, it is also applicable to a case of a photomask blank manufacturing method in which a resist bottom anti-reflective coating (BARC) or the like is formed under the resist film (i.e. on the opaque film) and a conductive film, a protective film, or the like is formed on the resist film. In this case, unnecessary-film removal can be implemented with respect to the BARC (resist bottom coating), the resist film, and the conductive film or protective film (resist top film), respectively, according to the method described in Example 1 or 2 as the example. Further, in this case, instead of the substrate formed with the opaque film, it may be a reflection mask substrate or the like having a reflective film, an absorbent, and so on stacked in layers. Further, it is also applicable to a phase-shift mask blank manufacturing method in which an SOG film is formed on an optically transparent substrate and an opaque film pattern is formed on the SOG film. In this case, it may also be provided with a film such as a transparent conductive film or an etching stopper film in addition to the opaque film.

Further, for example, it is also applicable to a case of removing an unnecessary film formed at the time of coating a protective film or lubricating film of a magnetic disk medium or at the time of coating a protective film of a color filter, or removing an insulating film formed at an electrode portion of wiring on a liquid crystal display substrate. Further, for example, when an unnecessary film is a resist, use can be made, as a chemical solution, of a liquid such as ketone, ester, aromatic hydrocarbon, halogenated hydrocarbon, or ether in which the resist is soluble.

Since the coating film after the heat treatment is difficult to dissolve, the removal of the unnecessary film is carried out before the heat treatment in the foregoing Examples 1 and 2. However, according to the type of a film to be removed, there is a case where dissolution is possible after the heat treatment. Further, the position where the chemical solution supply means is provided is not limited to the foregoing Examples.

In the foregoing Examples, the example is cited where the substrate and the cover member are integrally rotated, but they are not necessarily rotated. However, it is preferable to rotate them because the chemical solution can be spread into the clearance relatively fast and uniformly.

Further, in the foregoing Examples, the example is cited where the cover member is used for removing the peripheral portion of the coating film (resist film) formed on the square substrate to thereby leave the square coating film. However, the shape of the substrate and the shape of the coating film to remain are not limited to a square, but may be a circle, a triangle, a polygon, or any other arbitrary shape. In this case, the shapes of a chemical solution supply surface and non-supply surface of a cover member may be formed accordingly, and a rotation angle between the substrate and the cover member and a ration angle between the substrate and a substrate holding stage may be selected accordingly.

### EFFECT OF THE INVENTION

According to this invention, it is possible to provide the unnecessary-film removal apparatus, the unnecessary-film removal method, and the photomask blank manufacturing method that can securely remove the unnecessary resist residue at the peripheral portion of the substrate and, therefore, it is possible to securely prevent generation of dust from the peripheral portion of the substrate in the storage of the photomask blank and the later mask manufacturing process. Further, it is possible to finally reduce defects of or prevent a reduction in production yield of masks (including reticles) being the products using the photomask blank as a feed material.

Further, no limitation may be made to the removal of the unnecessary resist film at the peripheral portion only by the use of the solvent, but utilization can be considered as regards the developer supply means or method in the periphery (unnecessary portion) developing removal process according to the method of resist coating→periphery (unnecessary portion) exposure→periphery (unnecessary portion) developing removal→heat treatment. Industrially useful and significant effects can be accomplished. Specifically, the following effects are achieved.

1) By providing the chemical solution guide member forming the flow path for the chemical solution cooperatively with the shield member (cover member), the clearance between the shield member (cover member) and the chemical solution guide member and the flow rate of the chemical solution are adjusted while the clearance between the substrate and the shield member is maintained at the size that allows the chemical solution to enter the clearance and spread only in the clearance, so that the chemical solution supply amount to the unnecessary portion of the film formed on the surface of the substrate can be sufficient as required and is controllable, thereby securely preventing the residue after the removal of the unnecessary film.

2) There is provided the shield member (cover member) having, at three or more positions, the distance adjusting members that serve to adjust the distance with respect to the main surface of the substrate. The arrangement positions of the distance adjusting members are set such that, when the arrangement positions are connected to each other with a straight line, they are not located on the straight line and, when the shield member (cover member) is rotated with respect to the substrate by a predetermined angle about the center of the main surface of the substrate, they do not overlap the arrangement positions before the rotation, or the moving mechanism is provided wherein each of the distance adjusting members moves by a predetermined amount in parallel to the side direction of the substrate. Thereby, it is possible to securely prevent the residue after the removal of the unnecessary film at the positions where the shield member contacts the main surface of the substrate.

3) At the positions where the substrate holding means for holding the substrate contacts the substrate, the plurality of substrate holding members for holding the substrate are provided. The arrangement positions of the substrate holding members are set such that, when the substrate is rotated with respect to the substrate holding members by a predetermined angle, the arrangement positions of the substrate holding members do not overlap those before the rotation. Accordingly, by rotating the substrate with respect to the substrate holding members by the predetermined angle during the unnecessary-film removal process, it is possible to securely prevent the residue after the removal of the unnecessary film at the positions where the substrate and the substrate holding members contact each other.

1. An unnecessary-film removal apparatus for supplying a chemical solution only to an unnecessary portion of a film formed on a surface of a substrate including a peripheral portion thereof to thereby remove the unnecessary-film portion formed on the substrate, characterized by comprising:
substrate holding means for holding said substrate so as to allow in-plane rotation thereof;
chemical solution supply means for supplying said chemical solution;
a shield member covering the main surface of said substrate so as to form a constant clearance with respect to the main surface of said substrate in a removal area of the main surface of said substrate and form a space larger than said clearance in a non-removal area of the main surface of said substrate, said clearance being set to a size that allows said chemical solution to enter said clearance and to spread only in said clearance; and
a chemical solution guide member located outside said shield member so as to form a flow path for said chemical solution cooperatively with said shield member;
wherein said shield member and said chemical solution guide member being disposed so as to be rotatable along with said substrate holding means.

2. An unnecessary-film removal apparatus for supplying a chemical solution only to an unnecessary portion of a film formed on a surface of a substrate including a peripheral portion thereof to thereby remove the unnecessary-film portion, characterized by comprising;
substrate holding means for holding said substrate so as to allow in-plane rotation thereof;
chemical solution supply means for supplying said chemical solution; and
a shield member covering the main surface of said substrate so as to form a constant clearance with respect to the main surface of said substrate in a removal area of the main surface of said substrate and form a space larger than said clearance in a non-removal area of the main surface of said substrate;
said shield member being provided with distance adjusting members that are three or more in number and that face the main surface of said substrate such that said clearance is set to a size that allows said chemical solution to enter said clearance and spread only in said clearance;
arrangement positions of said distance adjusting members being set such that, when said arrangement positions are connected to each other with a straight line, they are not located on the straight line and, when said shield member is rotated with respect to said substrate by a predetermined angle about the center of the surface of said substrate, they do not overlap the arrangement positions of said distance adjusting members positioned before rotation;
said shield member being disposed so as to be rotatable along with said substrate holding means.

3. An unnecessary-film removal apparatus for supplying a chemical solution only to an unnecessary portion of a film formed on a surface of a substrate including a peripheral portion thereof to thereby remove the unnecessary-film portion, characterized by comprising:
substrate holding means for holding said substrate so as to allow in-plane rotation thereof;
chemical solution supply means for supplying said chemical solution; and
a shield member covering the main surface of said substrate so as to form a constant clearance with respect to the main surface of said substrate in a removal area of the main surface of said substrate and form a space larger than said clearance in a non-removal area of the main surface of said substrate;
said shield member being provided with distance adjusting members that are three or more in number and that face the main surface of said substrate such that said clearance is set to a size that allows said chemical solution to enter said clearance and spread only in said clearance;
arrangement positions of said distance adjusting members being set such that, when said arrangement positions are connected to each other with a straight line, they are not located on the straight line;
a moving mechanism being provided in which said distance adjusting members each move in parallel to a side direction of said substrate by a predetermined amount;
said shield member being disposed so as to be rotatable along with said substrate holding means.

4. An unnecessary-film removal apparatus for supplying a chemical solution only to an unnecessary portion of a film formed on a surface of a substrate including a peripheral portion thereof to thereby remove the unnecessary-film portion, characterized by comprising;
substrate holding means for holding said substrate so as to allow in-plane rotation thereof;
chemical solution supply means for supplying said chemical solution; and
a shield member covering the main surface of said substrate so as to form a constant clearance with respect to the main surface of said substrate in a removal area of the main surface of said substrate and to form a space larger than said clearance in a non-removal area of the main surface of said substrate, said clearance being set to a size that allows said chemical solution to enter said clearance and to spread only in said clearance;
said substrate holding means having a plurality of substrate holding members so as to hold said substrate at a plurality of positions on a bottom surface and side surfaces of said substrate;
arrangement positions of said substrate holding members being set such that, when said substrate is rotated with respect to said substrate holding members by a predetermined angle, the arrangement positions of said substrate holding members do not overlap previous ones positioned before rotation;
said shield member being disposed so as to be rotatable along with said substrate holding means.

5. An unnecessary-film removal method using the unnecessary-film removal apparatus according to claim 1, characterized by placing said substrate on said substrate holding means and supplying the chemical solution from said chemical solution supply means while integrally rotating said substrate, said shield member, and said chemical solution guide member so that the chemical solution is supplied only to the unnecessary portion of the film formed on the surface of said substrate including its peripheral portion through the flow path formed by said shield member and said chemical solution guide member, thereby removing the unnecessary film portion.

6. An unnecessary-film removal method using the unnecessary-film removal apparatus according to claim 2, characterized by placing said substrate on said substrate holding means and supplying the chemical solution from said chemical solution supply means while integrally rotating said substrate and said shield member so that the chemical solution is supplied only to the unnecessary portion of the film formed on the surface of said substrate including its peripheral portion along an outer wall of said shield member, thereby removing the unnecessary film portion, and thereafter, rotating said shield member with respect to said substrate by the predetermined angle about the center of the main surface of said substrate and removing the unnecessary film portion formed at positions where said distance adjusting members before rotation and said substrate were in contact with each other.

7. An unnecessary-film removal method using the unnecessary-film removal apparatus according to claim 3, characterized by placing said substrate on said substrate holding members of said substrate holding means and supplying the chemical solution from said chemical solution supply means while integrally rotating said substrate and said shield member so that the chemical solution is supplied only to the unnecessary portion of the film formed on the surface of said substrate including its peripheral portion along an outer wall of said shield member, thereby removing the unnecessary film portion, and thereafter, rotating said substrate holding means with respect to said substrate by the predetermined angle about the center of the main surface of said substrate and removing the unnecessary film portion formed at positions where said substrate holding members before rotation and said substrate were in contact with each other.

8. A photomask blank manufacturing method having a film forming process for forming a film such as an opaque film on an optically transparent substrate, said photomask blank manufacturing method characterized by comprising an unnecessary-film removal process for removing an unnecessary film formed at an unnecessary portion in said film forming process, by the use of the unnecessary-film removal method according to claim 5.
